(19) United States
(12) Patent Application Publication
(10) Pub. No.: US 2011/0180922 A1
(43) Pub. Date: Jul. 28, 2011

(54) SEMICONDUCTOR CHIP, SEAL-RING STRUCTURE AND MANUFACTURING PROCESS THEREOF

(75) Inventors: Kuo-Chiang Chen, Taipei County (TW); Yen-Yi Chen, Sanchong City (TW)

(73) Assignee: FORTUNE SEMICONDUCTOR CORPORATION, Taipei Hsien (TW)

(21) Appl. No.: 12/694,261

(22) Filed: Jan. 26, 2010

(51) Int. Cl. H01L 23/02; H01L 21/56; H01L 23/544

(52) U.S. Cl. 257/700; 438/124; 257/E21.502; 257/E23.18; 257/E23.179

(57) ABSTRACT

A semiconductor chip includes an integrated circuit region, at least one alignment indicator region and a seal-ring. The alignment indicator region is disposed near the integrated circuit region. The seal-ring surrounding the integrated circuit region is disposed outside of the integrated circuit region, and is formed as a mark for alignment on the alignment indicator region at a corner of the semiconductor chip. A manufacturing process of the seal-ring structure is also disclosed.

### BACKGROUND OF THE INVENTION

1. Field of the Invention

The present invention relates to a semiconductor chip, a seal-ring structure and manufacturing process thereof, in particular, to a seal-ring structure formed with a mark, which is applied for calibration and alignment to a semiconductor chip, and a manufacturing process for the seal-ring structure and the semiconductor chip.

2. Description of Related Art

Referring to FIG. 1, in which a top view of conventional semiconductor chip 1 is disclosed. The conventional semiconductor chip 1 includes an integrated circuit region 10, a mark 12 arranged at a corner of the semiconductor chip 1, and a seal-ring structure 14 arranged around the semiconductor chip 1. The integrated circuit region 10 includes various electronic devices, for example, an active and passive components formed on a substrate. Besides, the mark 12, which is an alignment mark adapted for optical beams, a scanning electron microscope (SEM) or other alignment equipments, is a subject for recognition and alignment by calibration equipments (not shown), so as to perform related testings and measurements of the semiconductor chip 1 precisely.

With respect to FIG. 1, the seal-ring structure 14 arranged on the semiconductor chip 1 is used to prevent electrostatic effects to the circuit region 10, to forbid mechanical cutter slicing over the circuit region 10, and further to stop the moisturizing, polluting or corrosive factors into the integrated circuit region 10. Referring to FIG. 2, in which a cross-sectional profile of the conventional semiconductor chip 1 is shown. The conventional semiconductor chip 1 includes a substrate 140, a plurality of sealing base layers 142, a plurality of dielectric layers 144, a plurality of contact layers 145, a plurality of metal layers 146, a protection layer 147 and an isolation layer 148.

Referring now to FIG. 2, the sealing base layers 142, arranged within the substrate 140, are raised sources/drains. The isolation layer 148, arranged on the substrate 140, is a field oxide (FOX) by achieving an insulation effect. The dielectric layers 144 are on/above the sealing base layers 142 and the isolation layer 148. Each of the metal layers 146 is arranged on each of the dielectric layers 144 and connected to the sealing base layers 142 via the contact layers 145. The protection layer 147 is depositing onto the topmost layer of the seal-ring structure 14 to prevent damage or pollution from the surface of the seal-ring structure.

In design, the corner of the conventional semiconductor chip 1 is over-occupied because of the ordinary setting with the mark 12 and the seal-ring structure 14 at the same time, and it will occupy too much chip area and lead to the low chip area utilization of the conventional semiconductor chip 1.

### SUMMARY OF THE INVENTION

In view of the aforementioned issues, the present invention provides a semiconductor chip and a seal-ring structure arranged on and around the semiconductor chip; the seal-ring structure at a corner of the semiconductor chip is considered as a mark for recognition and alignment.

To achieve the above-mentioned objectives, the present invention provides a semiconductor chip includes an integrated circuit region, at least one alignment indicator region at a corner of the semiconductor chip and a seal-ring structure. The alignment indicator region is disposed near the integrated circuit region. The seal-ring structure is disposed outside and around the integrated circuit region and the seal-ring structure in the alignment indicator region at a corner of the semiconductor chip is formed as a mark for alignment.

To achieve the above-mentioned objectives, the present invention further provides a manufacturing process of a seal-ring structure on a semiconductor chip. The steps includes: providing a substrate, which includes a sealing region, a marking region and a buffering region. The sealing region is disposed around the substrate, the marking region is disposed at a corner of the substrate, and the buffering region is disposed between the sealing region and the marking region. Then, a sealing base layer is formed within the sealing region and the marking region. After that, a sealing ring stack layer is formed on the sealing base layer for connecting the sealing base layer; a protection layer is formed on the sealing ring stack layer. Sequentially, a conformable area of the protection layer, which corresponds to the marking region, is removed.

To achieve the above-mentioned objectives, the present invention further provides a seal-ring structure on a semiconductor chip. The seal-ring structure includes a substrate, a sealing base layer, a sealing ring stack layer and a protection layer. The substrate includes a sealing region, a marking region and a buffering region. The sealing base layer is disposed within the sealing region and the marking region. The sealing ring stack layer is disposed on the sealing base layer for connecting the sealing base layer. The protection layer is disposed on the sealing ring stack layer, and is corresponding to the sealing region and the buffering region.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 is a top view of the conventional semiconductor chip;

FIG. 2 is a cross-sectional profile of the conventional seal-ring structure, which is applied to the conventional semiconductor chip;

FIG. 3 is a top view of a semiconductor chip according to a preferred embodiment of the present invention;

FIG. 4 is a cross-sectional profile of FIG. 3;

FIG. 5 is another cross-sectional profile of FIG. 3;

FIGS. 6-9 are top views of a mark according to various embodiments of the present invention; and

FIG. 10 is a flow chart of a seal-ring structure according to the present invention.

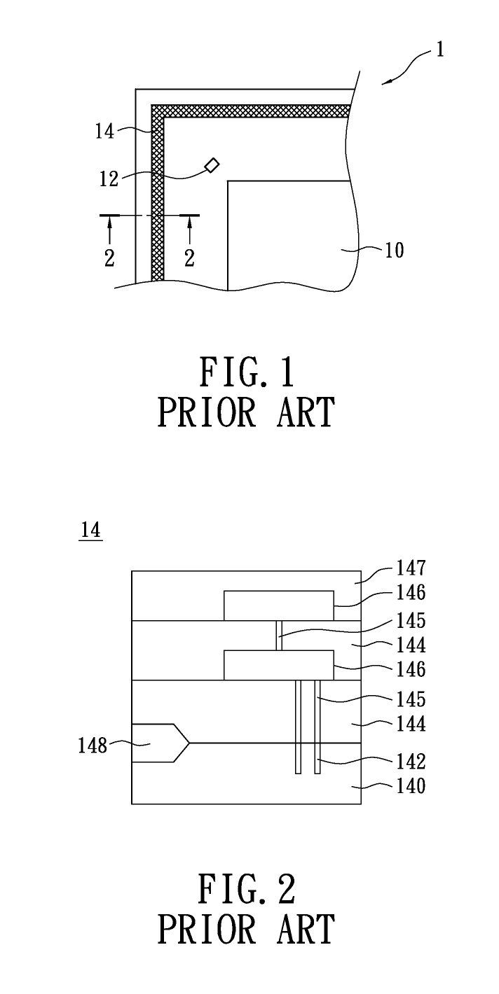

### DETAILED DESCRIPTION OF THE PREFERRED EMBODIMENTS

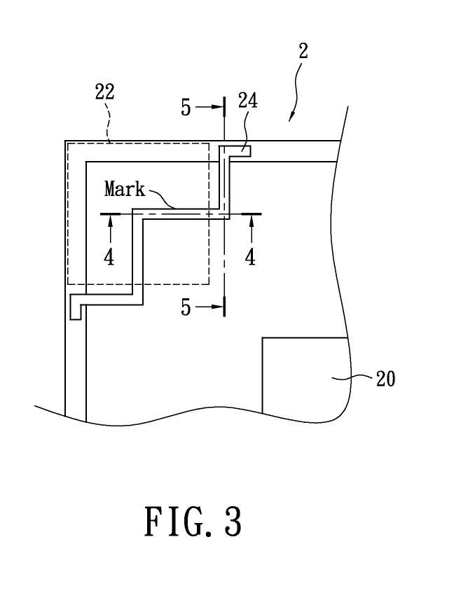

Referring now to FIG. 3, in which a top view of a semiconductor chip 2 of a preferred embodiment according to the present invention is shown. The semiconductor chip 2 includes an integrated circuit region 20, at least one alignment indicator region 22, and a seal-ring structure 24. The alignment indicator region 22, disposed near the integrated circuit region 20, is a non-circuit region. The seal-ring structure 24 in the alignment indicator region 22 at a corner of the semiconductor chip is disposed outside and around the integrated circuit region 20, and is formed as a mark for alignment.

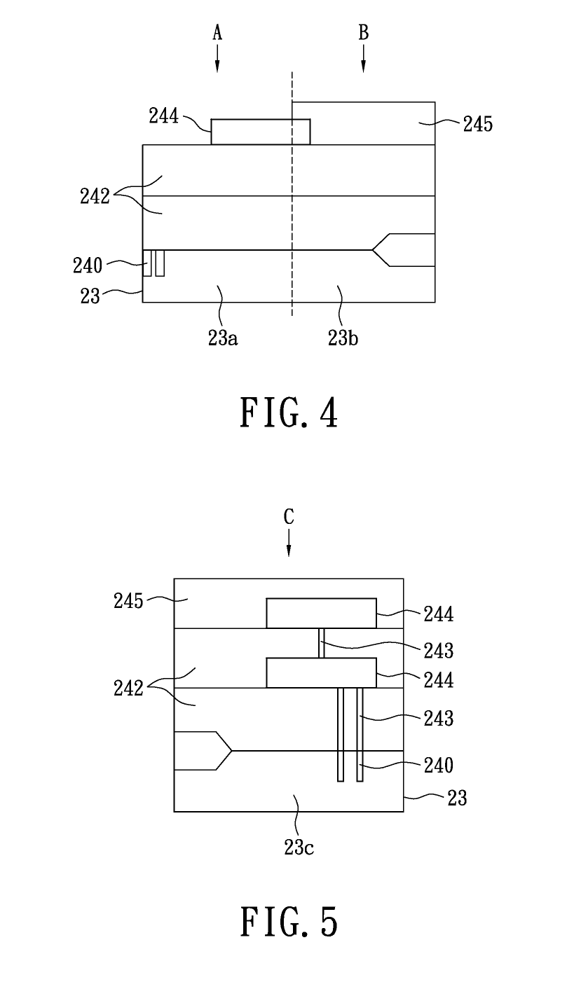

With respect to FIG. 3, referring now to FIG. 4, in which a cross-sectional profile of a portion of the seal-ring structure of FIG. 3 according to the present invention. The seal-ring structure 24, illustrated in FIG. 4, includes a marked seal-ring substructure A and a buffered seal-ring substructure B. The marked seal-ring substructure A is arranged within the alignment indicator region 22.

With respect to FIG. 3, referring now to FIG. 4, the marked seal-ring substructure A within the alignment indicator region 22 includes a substrate 23, a sealing base layer 240, a plurality of dielectric layers 242, and a top metal layer 244. The sealing base layer 240 is disposed within the substrate 23. The dielectric layers 242 are on/above the sealing layer 240. The top metal layer 244 is disposed on/above the dielectric layers 242 to electrically connect with the sealing base layer 240. The substrate 23 could be made of element semiconductors, such as silicon or germanium, or compound semiconductors, such as silicon carbide, gallium arsenide, indium arsenide, or indium phosphide. The sealing base layer 240 includes at least one raised source/drain. The dielectric layers 242 are made of but not restrained by silica, silicon nitride, silicon oxynitride, spin-on glass (SOG), and/or low dielectric constant materials.

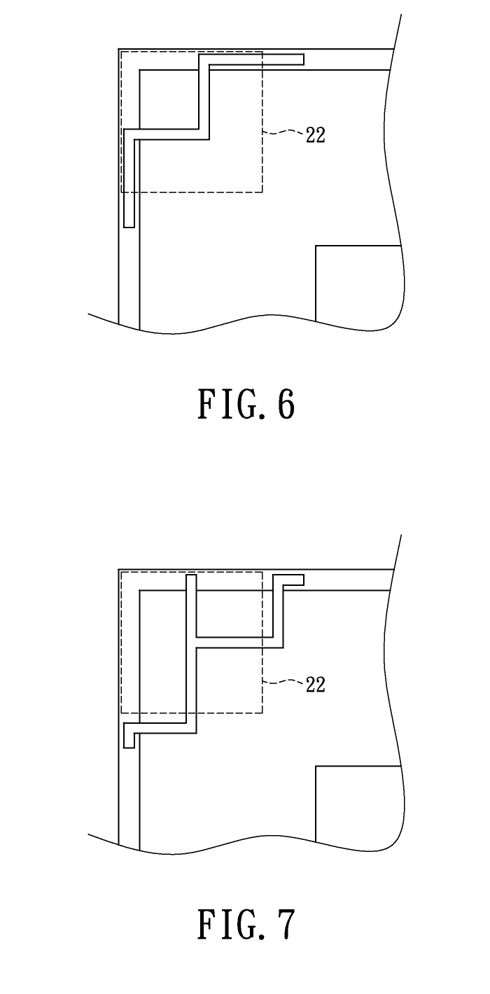

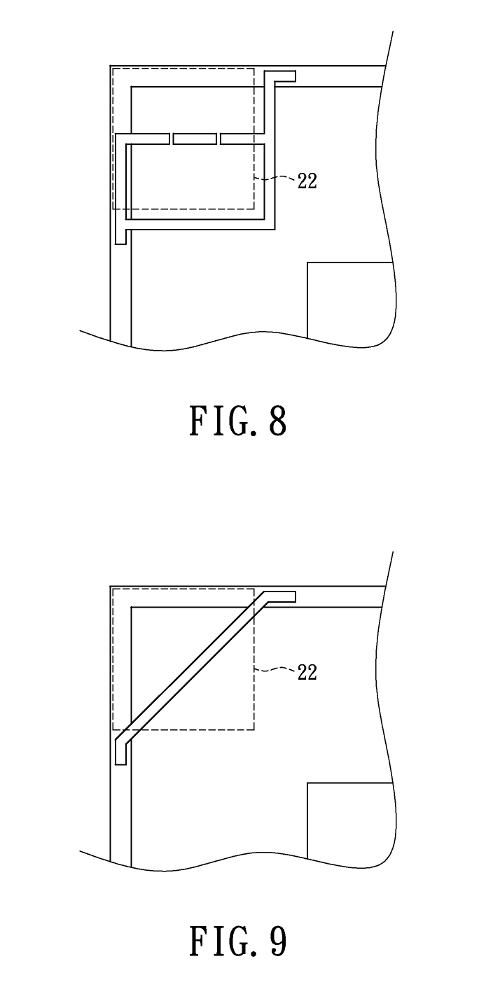

With respect to FIG. 3, referring now to FIG. 4, the mark for alignment Mark of the marked seal-ring substructure A within the alignment indicator region 22 at a corner of the semiconductor chip is made by the top metal layer 244, which can be designed into a L shape, a M shape, a T shape, a L shape in conjunction with a I shape, or a I shape. The mark for alignment Mark is a subject for recognition and alignment by calibration equipments (not shown), so as to perform related testings and measurements of the semiconductor chip 2 precisely, respectively referring to FIGS. 3, 6 and 9.

With respect to FIG. 3, referring now to FIG. 4, the buffered seal-ring substructure B is arranged outside the alignment indicator region 22 at the corner of the chip, and disposed between the alignment indicator region 22 and the integrated circuit region 20. The buffered seal-ring substructure B includes the substrate 23, the plurality of dielectric layers 242, the top metal layer 244 and a protection layer 245. The dielectric layers 242 are disposed on/above the substrate 23. The top metal layer 244 is disposed on/above the dielectric layers 242. The protection layer 245 covers the top metal layer 244 in order to prevent a surface of the buffered seal-ring substructure B from damage or pollution.

With respect to FIG. 3, referring now to FIG. 5, in which another cross-sectional profile of a portion of the seal-ring structure of FIG. 3. The seal-ring structure 24 further includes a stationary seal-ring substructure C. The stationary seal-ring substructure C is laid out on the exterior region of the alignment indicator region 22 at the corner of the semiconductor chip and is arranged outside the integrated circuit region 20. The stationary seal-ring substructure C connects the marked seal-ring substructure A via the buffered seal-ring substructure B.

With respect to FIG. 3, referring now to FIG. 5, the stationary seal-ring substructure C includes a substrate 23, a sealing base layer 240, two dielectric layers 242, two contact layers 243, two metal layers 244 and a protection layer 245. The sealing base layer 240 is disposed within the substrate 23. The two dielectric layers 242 are arranged on/above the sealing base layer 240. Each of the metal layers 244 is disposed on each of the dielectric layers 242 respectively. Each of the contact layers 243 is disposed within each of the dielectric layers 242 respectively and electrically connected with the adjacent metal layers 244 and the sealing base layer 240. The protection layer 245 is depositing onto the topmost layer of the metal layers 244.

With respect to FIG. 3, referring now to FIGS. 4 and 5, the seal-ring structure 24 is arranged on a semiconductor chip 2 and the configuration thereof at least includes the substrate 23, the sealing base layer 240, a sealing ring stack layer (not numbered) and the protection layer 245. The sealing ring stack layer includes the metal layers 244, the dielectric layers 2442 and the contact layers 243.

The substrate 23 of the seal-ring structure 24 according to the present invention contains a marking region 23a, a buffering region 23b and a sealing region 23c. Therein, the sealing base layer 240 is arranged within the marking region 23a and the sealing region 23c. The sealing ring stack layer is formed on the sealing base layer 240 and connected with the substrate 23. The protection layer 245 is formed on the sealing ring stack layer in correspondence with the buffering region 23b and the sealing region 23c.

Referring now to FIGS. 4 and 5, the structure of the sealing ring stack layer of the seal-ring structure 24 corresponding with the sealing region 23c includes two dielectric layers 242, two metal layers 244 and two contact layers 243 according to the present invention. Each metal layer 244 is disposed on a respective one of the dielectric layers 242; each contact layer 243 is disposed within a respective one of the dielectric layers 242 for electrically connecting the metal layers 244 to the sealing base layer 240. Additionally, the structure of the sealing ring stack layer of the seal-ring structure 24 corresponding with the marking region 23a and the buffering region 23b includes two dielectric layers 242 and the top metal layer 244, wherein the top metal layer 244 is arranged on/above the two dielectric layers 242.

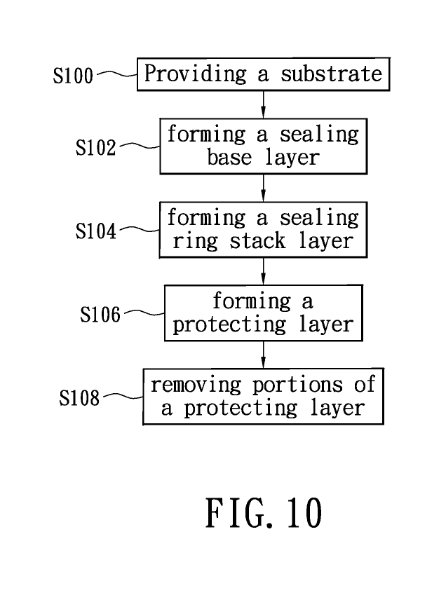

With respect to FIGS. 4 and 5, referring now to FIG. 10, in which a flow chart of manufacturing the seal-ring structure on the semiconductor chip according to the present invention is disclosed. The manufacturing process includes the steps of: providing a substrate 23, which includes a marking region 23a, a buffering region 23b and a sealing region 23c, in step S100. The sealing region 23c is disposed around the substrate 23; the marking region 23a is disposed at a corner of the substrate 23; and the buffering region 23b is disposed between the sealing region 23c and the marking region 23a. In step S102, forming a sealing base layer 240 within the marking region 23a and the sealing region 23c. In step S 104, forming a sealing ring stack layer on the sealing base layer 240 for connecting the sealing base layer 240.

In step S104, is can be completed by the following steps: first, forming two dielectric layers 242 on/above the sealing base layer 240 within the sealing region 23c. Then, two metal layers 244 are respectively formed on the two dielectric layers 242. Furthermore, two contact layers 243 are respectively formed within the dielectric layers 242, to connect the metal layers 244 to the sealing base layer 240. Meanwhile, the two dielectric layers 242 are formed on/above the sealing base layer 240 within the marking region 23a, and then the top metal layer 244 is formed on/above the two dielectric layers 242. Also, the two dielectric layers 242 are formed on/above the sealing base layer 240 within the buffering region 23b, and then the top metal layer 244 is formed on/above the two dielectric layers 242.

The contact layers 243, referred to the aforementioned embodiments, could be made by steps of: forming cavities of the dielectric layers 242, depositing metallic materials into the cavities, and etching partial metallic materials via etch-back method. The Physical Vapor Depositing method (PVD) or the Chemical Vapor Depositing method (CVD) could be offered to deposit the metallic materials. The metallic materials could be selected at least from titanium, tungsten, aluminum, silver, copper, alloy or the like. The metallic materials remained in the cavities are treated as the contact layers 243.

At step S106, forming a protection layer 245 on the sealing ring stack layer, is sequentially provided. At step S108, a conformable area of the protection layer 245, which corresponds to the marking region 23a, is removed. The conformable area could be removed by an etching stage under a photolithography process, in which the conditions and technologies are conventional and no detailed description is required.

The semiconductor chip according to the present invention provides the mark for alignment, formed by the seal-ring structure which is laid out at a corner thereof, so that the mark could be a subject for recognition and alignment by calibration equipments (not shown). The seal-ring structure regarding the semiconductor chip according to the present invention is functioned of the conventional seal-ring structure and the subject for recognition and alignment. Therefore, there is no necessary to provide an extra calibration mark on the semiconductor chip, so as to improve and increase the area utilization of the semiconductor chip effectively.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A semiconductor chip, comprising:
an integrated circuit region;
at least one alignment indicator region disposed near the integrated circuit region; and
a seal-ring structure being surrounding the integrated circuit region and being disposed outside of the integrated circuit region, thereby forming a mark within the alignment indicator region.

2. The semiconductor chip according to claim 1, wherein the seal-ring structure includes a marked seal-ring substructure disposed within the alignment indicator region.

3. The semiconductor chip according to claim 2, wherein the marked seal-ring structure includes:
a sealing base layer;
a plurality of dielectric layers being disposing above the sealing layer; and
a top metal layer disposed above the plurality of dielectric layers and electrically connected with the sealing base layer.

4. The semiconductor chip according to claim 3, wherein the sealing base layer is disposed within a substrate, and includes at least one raised source/drain.

5. The semiconductor chip according to claim 3, wherein the top metal layer is forming as the mark.

6. The semiconductor chip according to claim 5, wherein the shape of the mark is a L shape, a T shape or a I shape.

7. The semiconductor chip according to claim 2, wherein the seal-ring structure includes a stationary seal-ring substructure disposed outside the integrated circuit region.

8. The semiconductor chip according to claim 7, wherein the stationary seal-ring substructure includes:
a sealing base layer;
a plurality of dielectric layers, being disposing above the sealing layer;
a plurality of metal layers, respectively disposed on the dielectric layers;
a plurality of contact layers, respectively disposed within the dielectric layers and electrically connected with the two adjacent metal layers and the sealing base layer; and
a protection layer, being depositing onto a top metal layer out of the plurality of the metal layers.

9. The semiconductor chip according to claim 8, wherein the sealing base layer is disposed within a substrate, and includes at least one raised source/drain.

10. The semiconductor chip according to claim 7, wherein the seal-ring structure includes a buffered seal-ring substructure disposed between marked seal-ring substructure and the stationary seal-ring substructure.

11. The semiconductor chip according to claim 10, wherein the buffered seal-ring substructure includes:
a substrate;
a plurality of dielectric layers, being disposing above the substrate
a top metal layer, being disposing above the plurality of dielectric layers; and
a protection layer, depositing onto the top metal layer.

12. The semiconductor chip according to claim 1, wherein the seal-ring structure includes a stationary seal-ring substructure, a marked seal-ring substructure and a buffered seal-ring substructure; wherein
the stationary seal-ring substructure includes:
a substrate;
a sealing base layer, being disposing within the substrate;
a plurality of dielectric layers, being disposing above the sealing base layer;
a plurality of metal layers, respectively disposed on the dielectric layers;
a plurality of contact layers, respectively disposed within the dielectric layers and electrically connected with the two adjacent metal layers and the sealing base layer; and
a protection layer, being depositing onto a top metal layer out of the plurality of the metal layers;
the marked seal-ring substructure includes:
the substrate
the sealing base layer, being disposing within the substrate;
the dielectric layers, being disposing above the sealing base layer; and
the top metal layer, disposed above the plurality of dielectric layers and electrically connected with the sealing base layer.

13. The semiconductor chip according to claim 12, wherein the buffered seal-ring substructure includes:
the substrate;
the plurality of dielectric layers, being disposing above the substrate;
the top metal layer, being disposing above the plurality of dielectric layers; and
a protection layer, being depositing onto the top metal layer.

14. A manufacturing process of a seal-ring structure on a semiconductor chip, comprising:
providing a substrate, which includes a sealing region, a marking region and a buffering region; the sealing region disposed around the substrate, the marking region disposed at a corner of the substrate, and the buffering region disposed between the sealing region and the marking region;
forming a sealing base layer within the sealing region and the marking region;
forming a sealing ring stack layer on the sealing base layer for connecting the sealing base layer;
forming a protection layer on the sealing ring stack layer; and
removing the protection layer corresponding with the marking region.

15. The manufacturing process according to claim 14, wherein in the step of removing the protection layer, a photolithography process is preformed by etching away the protection layer corresponding with the marking region.

16. The manufacturing process according to claim 15, wherein the step of forming the sealing ring stack layer includes:
forming a plurality of dielectric layers above the sealing base layer corresponding with the sealing region;
forming a plurality of metal layers respectively on the plurality of dielectric layers; and
forming a plurality of contact layers respectively within the dielectric layers, for connecting the two adjacent metal layers with the sealing base layer.

17. The manufacturing process according to claim 16, wherein the step of forming the sealing ring stack layer further includes:
forming a plurality of dielectric layers above the sealing base layer corresponding with the marking region; and
forming a top metal layer above the plurality of dielectric layers.

18. The manufacturing process according to claim 17, wherein the step of forming the sealing ring stack layer includes:
forming the plurality of dielectric layers over the buffering region; and
forming the top metal layer above the plurality of dielectric layers.

19. A seal-ring structure on a semiconductor chip comprising:
a substrate including a sealing region, a marking region and a buffering region;
a sealing base layer, being disposing within the sealing region and the marking region;
a sealing ring stack layer, being disposing on the sealing base layer for connecting the sealing base layer; and
a protection layer, being depositing onto the sealing ring stack layer and corresponding to the sealing region and the buffering region.

20. The seal-ring structure according to claim 19, wherein the sealing ring stack layer corresponding with the sealing region includes:
a plurality of dielectric layers;
a plurality of metal layers, being disposing above the dielectric layers; and
a plurality of contact layers, respectively disposed within the dielectric layers, for connecting the two adjacent metal layers with the sealing base layer.

21. The seal-ring structure according to claim 19, wherein the sealing ring stack layer corresponding with the marking region includes:
a plurality of dielectric layers; and
a top metal layer, disposed above the plurality of dielectric layers.

22. The seal-ring structure according to claim 19, wherein the sealing ring stack layer corresponding with the buffering region includes:
a plurality of dielectric layers; and
a top metal layer, disposed above the plurality of dielectric layers.
